(19) United States
(12) Patent Application Publication
(10) Pub. No.: US 2023/0099419 A1
(43) Pub. Date: Mar. 30, 2023

(54) ARTIFICIAL INTELLIGENCE DEVICE CELL WITH IMPROVED PHASE CHANGE MATERIAL REGION

(71) Applicant: International Business Machines Corporation, Armonk, NY (US)

(72) Inventors: Injo OK, Loudonville, NY (US); Kevin W. BREW, Niskayuna, NY (US); Iqbal Rashid SARAF, Glenmont, NY (US); Nicole SAULNIER, Slingerlands, NY (US)

(21) Appl. No.: 17/484,312

(22) Filed: Sep. 24, 2021

(51) Int. Cl. H01L 45/00

(52) U.S. Cl. CPC H01L 45/06; H01L 45/126; H01L 45/144; H01L 45/16

(57) ABSTRACT

An apparatus includes a heater, a phase change material region, and a top metal layer. The phase change material region includes a doped GST layer and a first GST layer. The first GST layer is between the doped GST layer and the heater, and the doped GST layer is doped differently than the first GST layer. The phase change material region is positioned between the heater and the top metal layer.

### BACKGROUND

The present disclosure relates to artificial intelligence, and more specifically, to an artificial intelligence device cell. Artificial intelligence devices use phase change materials (PCMs) in cells to store information. For example, the phase of the PCM can be altered or changed to represent changes in stored states or information for the artificial intelligence device. Some PCM materials (e.g., doped germanium-antimony-tellurium (GST)), however, may cause issues for other components of the cell. For example, oxygen from doped GST may damage heaters or the top metal in the cell.

### SUMMARY

According to an embodiment, an apparatus includes a heater, a phase change material region, and a top metal layer. The phase change material region includes a doped GST layer and a first GST layer. The first GST layer is between the doped GST layer and the heater, and the doped GST layer is doped differently than the first GST layer. The phase change material region is positioned between the heater and the top metal layer. Other embodiments include a method for forming the apparatus.

According to another embodiment, an apparatus includes a heater and a phase change material region. The phase change material region includes a doped GST layer disposed on a first GST layer. The first GST layer is between the doped GST layer and the heater, and the doped GST layer is doped differently than the first GST layer. Other embodiments include a method for forming the apparatus.

### BRIEF DESCRIPTION OF THE SEVERAL VIEWS OF THE DRAWINGS

FIG. 1 illustrates an example system.

FIG. 2 illustrates an example PCM cell in the system of FIG. 1.

FIG. 3 illustrates an example PCM region in the PCM cell of FIG. 2.

FIG. 4 is a flowchart showing an example method for forming the PCM cell of FIG. 2.

FIG. 5A illustrates a step in the formation of the PCM cell of FIG. 2.

FIG. 5B illustrates a step in the formation of the PCM cell of FIG. 2.

FIG. 5C illustrates a step in the formation of the PCM cell of FIG. 2.

FIG. 5D illustrates a step in the formation of the PCM cell of FIG. 2.

FIG. 5E illustrates a step in the formation of the PCM cell of FIG. 2.

FIG. 5F illustrates a step in the formation of the PCM cell of FIG. 2.

### DETAILED DESCRIPTION

This disclosure contemplates an artificial intelligence device cell with a phase change material (PCM) region that includes buffer layers that separate a doped germanium-antimony-tellurium (GST) layer from a heater and top metal in the cell. For example, GST layers may be formed above and below the doped GST layer such that the GST layers are positioned between the doped GST layer and the heater and top metal. The doped GST layer may be doped differently than the other GST layers. For example, the doped GST layer may be doped using silicon dioxide while the other GST layers are undoped or doped using nitrogen or another dopant that does not include oxygen. As a result, the GST layers may prevent the doped GST layer from oxidizing and damaging the heater and the top metal, in certain embodiments.

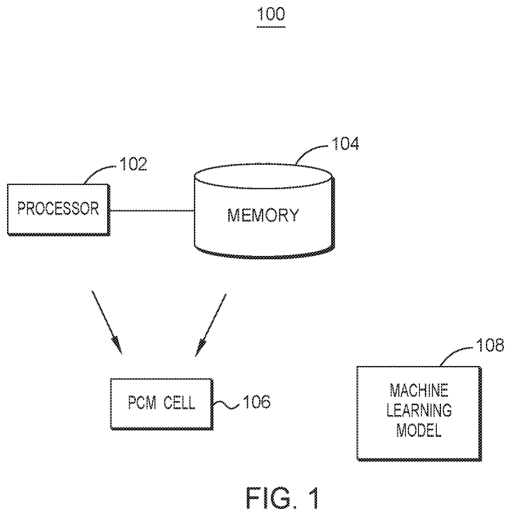

FIG. 1 illustrates an example system 100. The system 100 may be a computing system that includes a processor 102 and a memory 104. The processor 102 and the memory 104 may implement an artificial intelligence device that uses a PCM to store states or information. The processor 102 and the memory 104 perform the functions or actions of the computing system described herein.

The processor 102 is any electronic circuitry, including, but not limited to one or a combination of microprocessors, microcontrollers, application specific integrated circuits (ASIC), application specific instruction set processor (ASIP), and/or state machines, that communicatively couples to memory 104 and controls the operation of the computing system. The processor 102 may be 8-bit, 16-bit, 32-bit, 64-bit or of any other suitable architecture. The processor 102 may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The processor 102 may include other hardware that operates software to control and process information. The processor 102 executes software stored on the memory 104 to perform any of the functions described herein. The processor 102 controls the operation and administration of the computing system by processing information (e.g., information received from the memory 104). The processor 102 is not limited to a single processing device and may encompass multiple processing devices.

The memory 104 may store, either permanently or temporarily, data, operational software, or other information for the processor 102. The memory 104 may include any one or a combination of volatile or non-volatile local or remote devices suitable for storing information. For example, the memory 104 may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory 104, a disk, a CD, or a flash drive. In particular embodiments, the software may include an application executable by the processor 102 to perform one or more of the functions described herein.

The system 100 includes a PCM cell 106 (e.g., as part of the memory 104), which may also be referred to as a phase change memory cell. In certain embodiments, the PCM cell 106 is part of the memory 104. The PCM cell 106 includes a PCM that changes phases based on an amount of heat applied to the PCM (e.g., by applying an electric voltage or current to a heating element connected to the PCM). The phase of the PCM cell 106 may be used to represent state or information for an artificial intelligence device. For example, one or more PCM cells 106 may be used to store the different states of a neural network. As another example, one or more PCM cells 106 may be used to store the values in nodes of a graph or tree. The phases of the one or more PCM cells 106 may be adjusted to represent a change in the neural network, graph, or tree. A notable difference between PCM cells 106 and conventional memory is that PCM cells 106 may not be limited to storing binary states (e.g., a 0 or a 1). Rather, the phase of a PCM cell 106 may be used to represent multiple, different states.

The processor 102 and the memory 104 implement a machine learning model 108 that uses the PCM cell 106. For example, the machine learning model 108 may store state information using the PCM cell 106. As the state information changes (e.g., during training of the machine learning model 108), the phase of the PCM cell 106 is adjusted to represent the change in the state information. With enough PCM cells 106, the PCM cells 106 may store the machine learning model 108.

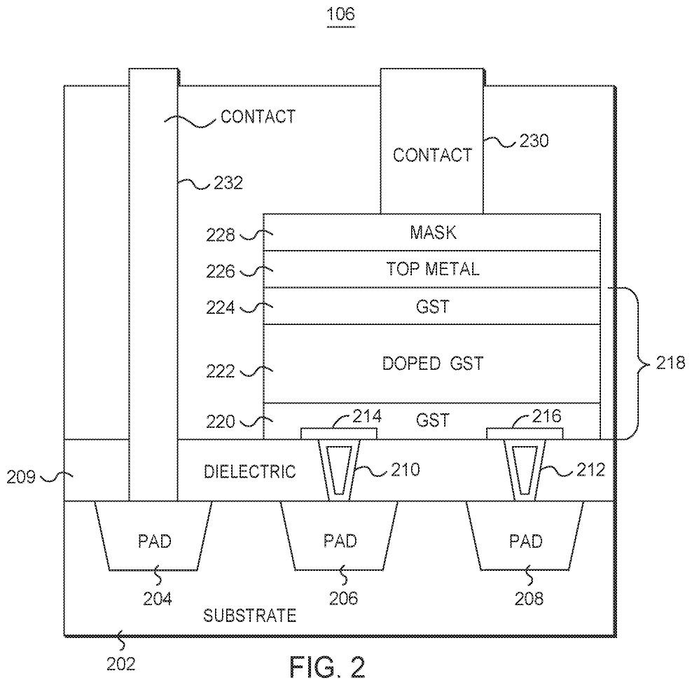

FIG. 2 illustrates an example PCM cell 106 in the system 100 of FIG. 1. A PCM region 218 in the PCM cell 106 includes additional layers that protect other components within the PCM cell 106 from oxidation. As a result, the PCM cell 106 has improved thermal stability, improved resistance drift, and reduced oxidation in certain embodiments. Additionally, the PCM cell 106 may be free of wet damage.

The PCM cell 106 includes a substrate 202 that serves as the foundation of the PCM cell 106. The substrate 202 may include any suitable material (e.g., silicon, metal oxide, or gallium arsenide). Pads 204, 206, and 208 are formed in the substrate 202. The pads 204, 206 and 208 may include any suitable conductive material. The pads 204, 206, and 208 conduct electric currents to or from other components of the PCM cell 106 connected to the pads 204, 206 and 208. A dielectric 209 is disposed on the substrate 202. The dielectric 209 may include any suitable insulative material (e.g., silicon nitride). The dielectric 209 may cover the substrate 202 and the pads 204, 206, and 208.

One or more heaters are formed in the dielectric 209. In the example of FIG. 2, heaters 210 and 212 are formed in the dielectric 209 such that the heaters 210 and 212 extend through the dielectric 209 to the pads 206 and 208, respectively. Because the heaters 210 and 212 connect to the pads 206 and 208, electric current may be conducted from the pads 206 and 208 to the heaters 210 and 212. The heaters 210 and 212 may include multiple layers of resistive materials. For example, the heaters 210 and 212 may include alternating layers of titanium nitride and tantalum nitride. In some embodiments, the heaters 210 and 212 include alternating layers of a low resistive material and a high resistive material. The heaters 210 and 212 generate heat when electrical current is applied to the heaters 210 and 212 from the pads 206 and 208. By adjusting the amount of electrical current applied to the heaters 210 and 212, the amount of heat generated by the heaters 210 and 212 is adjusted. For example, when the electric current applied to the heaters 210 and 212 is increased, the heaters 210 and 212 generate an increased amount of heat. As another example, when the electric current applied to the heaters 210 and 212 is decreased, the heaters 210 and 212 generate less heat. In some embodiments, the heaters 210 and 212 have a width that is less than or equal to 40 nanometers.

In some embodiments, liners 214 and 216 are formed on the heaters 210 and 212 (e.g., by deposition). The liners 214 and 216 may include a resistive material that improves the resistance drift in the PCM cell 106. The liners 214 and 216 are optional—some embodiments of the PCM cell 106 do not include the liners 214 and 216.

A PCM region 218 is formed on the dielectric 209 and the heaters 210 and 212. The PCM region 218 includes a PCM and protective layers. In the example of FIG. 2, the PCM region 218 includes a GST layer 220 formed on the dielectric 209 (e.g., by deposition). In embodiments that include the liners 214 and 216, the GST layer 220 is formed such that the liners 214 and 216 are within the GST layer 220. The PCM region 218 also includes a doped GST layer 222 formed on the GST layer 220 (e.g., by deposition). The doped GST layer 222 may include GST that has been doped using any suitable material, such as silicon dioxide. Additionally, another GST layer 224 is formed on the doped GST layer 222 (e.g., by deposition). The doped GST layer 222 may be doped differently than the GST layers 220 and 224. For example, the doped GST layer 222 may be doped using silicon dioxide while the GST layers 220 and 224 are undoped or doped using nitrogen or another dopant that does not include oxygen. As a result, the GST layers 220 and 224 protect other components of the PCM cell 106 from oxidation resulting from the doped GST layer 222 (e.g., from deposition of the doped GST layer 222). In some embodiments, the GST layers 220 and 224 and the doped GST layer 222 are formed in one chamber during the fabrication process.

The thickness of the doped GST layer 222 may be greater than the thicknesses of the GST layers 220 and 224. For example, the doped GST layer 222 may be 80 nanometers thick and the GST layers 220 and 224 may each be 1 to 5 nanometers thick. In some embodiments, the doped GST layer 222 is at least ten times as thick as the GST layers 220 and 224. Thus, the GST layers 220 and 224 are thick enough to block oxygen from the doped GST layer 222, but not so thick as to affect the resistance of the doped GST layer 222.

When the pads 206 and 208 apply electrical current to the heaters 210 and 212, the heaters 210 and 212 generate heat. The heat travels to the PCM region 218 and causes the doped GST layer 222 to change phases. By adjusting the electrical current applied to the heaters 210 and 212, the amount of heat applied to the doped GST layer 222 is adjusted. Thus, the phase of the doped GST layer 222 is changed and controlled. The GST layers 220 and 224 protect the heaters 210 and 212, the liners 214 and 216 (if present), and the top metal 226 from oxidation caused by the doped GST layer 222.

A top metal layer 226 is formed on the GST layer 224 (e.g., by deposition). Additionally, a mask 228 is formed on the top metal 226 (e.g., by deposition). Because the doped GST layer 222 is doped differently than the GST layers 220 and 224, the GST layers 220 and 224 protect the heaters 210 and 212 and the top metal 226 from oxidation caused by the doped GST layer 222.

Contacts 230 and 232 are formed in the PCM cell 106 so that electrical connections may be made to the pad 204 and the top metal 226 and mask 228. In the example of FIG. 2, the contact 230 is formed from the top of the PCM cell 106 to the mask 228. The contact 230 allows an electrical connection to be made to the mask 228 and the top metal 226. The contact 232 is formed from the top of the PCM cell 106 to the pad 204. The contact 232 allows an electrical connection to be made to the pad 204. In some embodiments, the contacts 230 and 232 are formed through an interlayer dielectric that is separate from the dielectric 209. The interlayer dielectric includes any suitable insulative material.

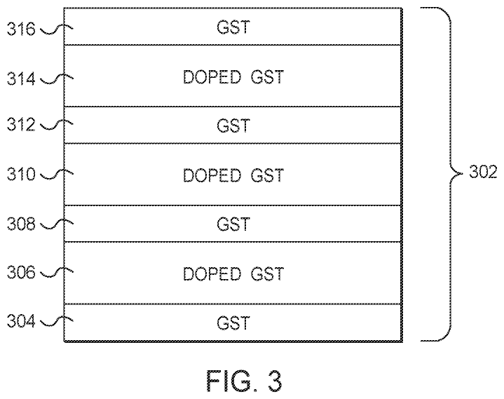

Some embodiments of the PCM cell 106 include a different structure for the PCM region 218. FIG. 3 illustrates an example PCM region 302 that may be implemented in the PCM cell 106 of FIG. 2. As seen in FIG. 3, the PCM region 302 includes multiple alternating layers of GST and doped GST. As with the example of FIG. 2, the doped GST layers are doped differently from the other GST layers. For example, the doped GST layers may be doped with silicon dioxide while the other GST layers are undoped or doped with nitrogen or another dopant that does not include oxygen. The PCM region 302 includes a GST layer 304 at the bottom of the PCM region 302. A doped GST layer 306 is formed on the GST layer 304. Another GST layer 308 is formed on the doped GST layer 306. Another doped GST layer 310 is formed on the GST layer 308. A GST layer 312 is formed on the doped GST layer 310. Yet another doped GST layer 314 is formed on the GST layer 312, and a GST layer 316 is formed on the doped GST layer 314. The PCM region 302 may include any suitable number of layers of GST and doped GST.

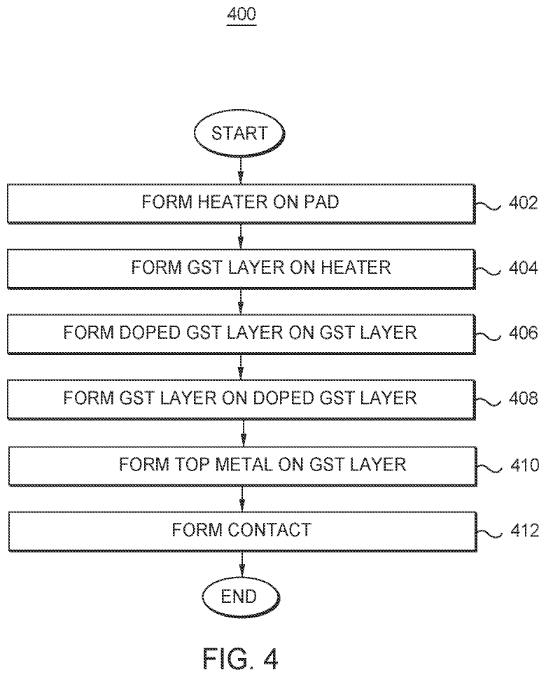

FIG. 4 is a flowchart showing an example method 400 for forming the PCM cell 106 of FIG. 2. In particular embodiments, a semiconductor fabrication machine or an operator perform the method 400. By performing the method 400, a PCM cell 106 that includes protective layers is formed.

In block 402, a heater 210 is formed on a pad 206. The pad 206 may be formed in a substrate 202 that serves as the foundation of the PCM cell 106. The heater 210 may include multiple layers of resistive materials. An electric current may be applied from the pad 206 to the heater 210 to cause the heater 210 to generate heat.

In block 404, a GST layer 220 is formed on the heater 210. For example, the GST layer 220 may be deposited on the heater 210. In some embodiments, a liner 214 is formed on the heater 210 before forming the GST layer 220 on the heater 210. In these embodiments, the liner 214 is positioned within the GST layer 220 after the GST layer 220 is formed on the heater 210.

In block 406, a doped GST layer 222 is formed on the GST layer 220. For example, the doped GST layer 222 may be deposited onto the GST layer 220. The doped GST layer 222 includes GST that has been doped with any suitable material (e.g., silicon dioxide or nitrogen). Another GST layer 224 is then formed on the doped GST layer 222 in block 408. In certain embodiments, the GST layer 220, the doped GST layer 222, and the GST layer 224 may all be deposited in one chamber of a semiconductor fabrication process.

In block 410, a top metal 226 is formed on the GST layer 224. In some embodiments, a mask 228 is then formed on the top metal 226. In block 412, a contact 230 is formed above the top metal 226. In some embodiments, the contact 230 is formed on the mask 228 that is formed on the top metal 226. The contact 230 allows an electrical connection to be made to the top metal 226.

In some embodiments, the doped GST layers 222 is significantly thicker than the GST layers 220 and 224. For example, the doped GST layer 222 may be 80 nanometers thick and the GST layers 220 and 224 are 1 to 5 nanometers thick. In some embodiments, the doped GST layer 222 is at least ten times as thick as the GST layers 220 and 224. As a result, the GST layers 220 and 224 protect the heater 210 and the top metal 226 from oxidation caused by the doped GST layer 222. Additionally, the GST layers 220 and 224 do not significantly affect the resistance of the doped GST layer 222.

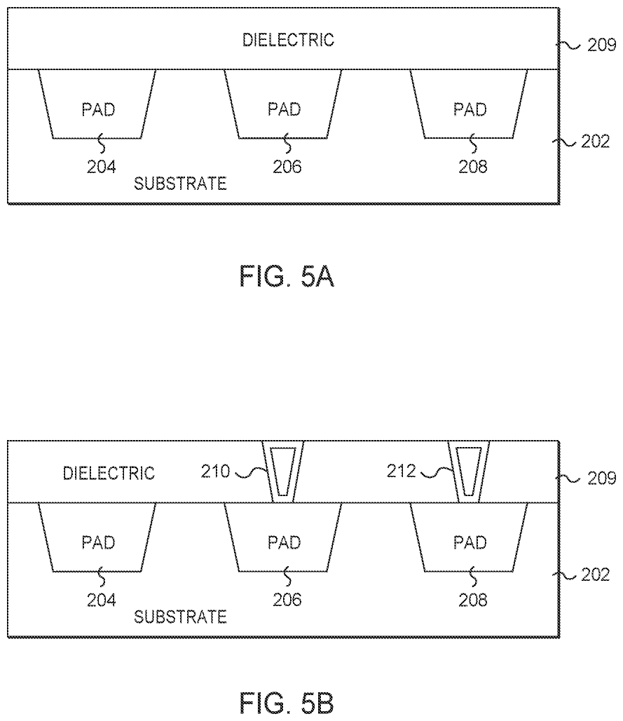

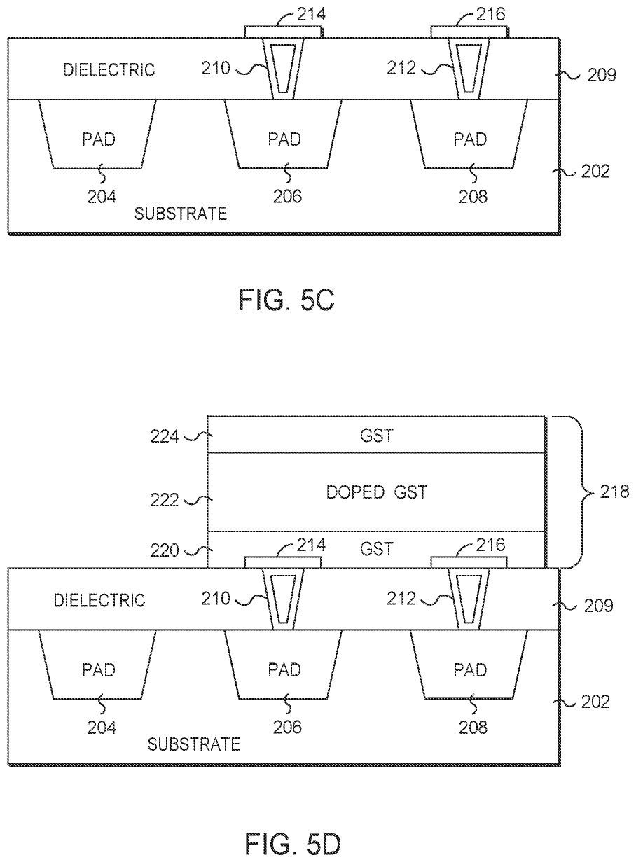

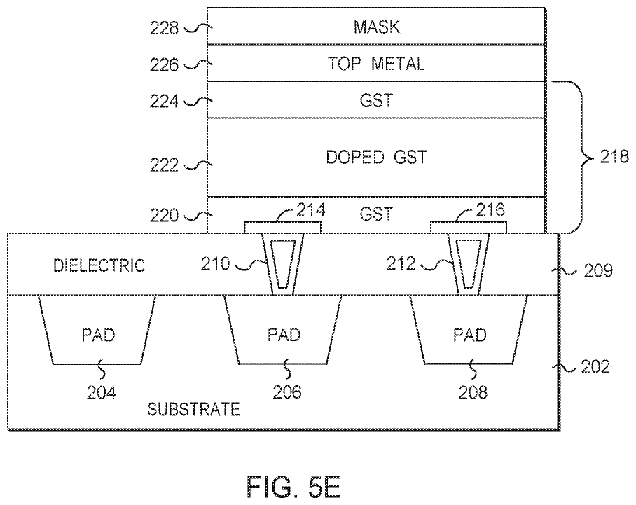

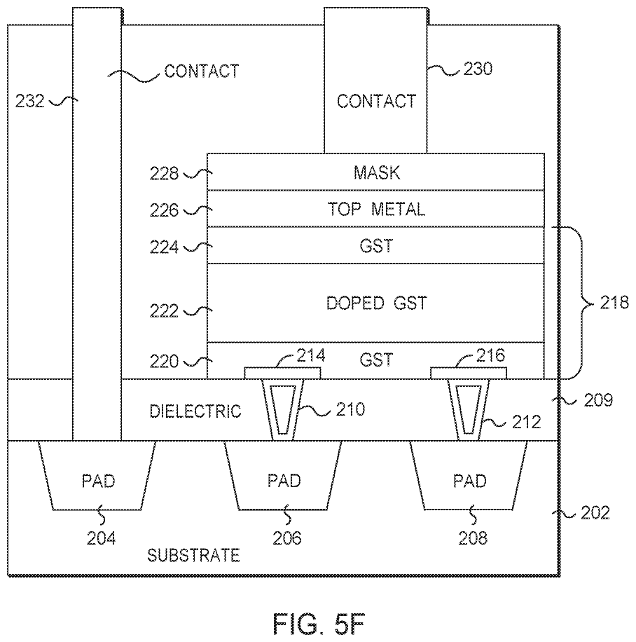

FIGS. 5A through 5F illustrate steps in the formation of the PCM cell 106 of FIG. 2. As seen in FIG. 5A, the dielectric 509 is formed on the substrate 202. Pads 204, 206, and 208 are formed in the substrate 202. The substrate 202 may include any suitable material, such as silicon, metal oxide, or gallium arsenide. The dielectric 209 may include any suitable insulative material. In some embodiments, the dielectric 209 is approximately 50 nanometers thick.

Heaters 210 and 212 are then formed through the dielectric 209. As seen in FIG. 5B, the heaters 210 and 212 are formed through the dielectric 209 to the pads 206 and 208, respectively. The heaters 210 and 212 may include alternating layers of resistive materials. When an electrical current is applied to the heaters 210 and 212 through the pads 206 and 208, the heaters 210 and 212 generate heat. As seen in FIG. 5C, liners 214 and 216 are then formed on the heaters 210 and 212. The liners 214 and 216 may be deposited on the heaters 210 and 212. Additionally, the liners 214 and 216 are formed on the dielectric 209. The liners 214 and 216 are optional—some embodiments do not includes the liners 214 and 216.

The PCM region 218 is then formed on the dielectric 209. As seen in FIG. 5D, the PCM region 218 is formed on the dielectric 209 above the heaters 210 and 212. In embodiments that include the liners 214 and 216, the liners 214 and 216 are positioned within the PCM region 218 after the PCM region 218 is formed. Additionally, the PCM region 218 includes a GST layer 220 formed on the dielectric 209 (e.g., by deposition). A doped GST layer 222 is formed on the GST layer 220 (e.g., by deposition), and the GST layer 224 is formed on the doped GST layer 222 (e.g., by deposition). The thickness of the doped GST layer 222 may be substantially greater than the thicknesses of the GST layers 220 and 224. In some embodiments, the doped GST layer 222 is at least ten times as thick as the GST layers 220 and 224. When electrical current is applied to the heaters 210 and 212 such that the heaters 210 and 212 generate heat, the heat causes the phase of the doped GST layer 222 to change. The amount of heat generated by the heaters 210 and 212 may be adjusted to adjust the phase of the doped GST layer 222.

As seen in FIG. 5E, a top metal 226 is then formed on the GST layer 224. A mask 228 is then formed on the top metal 226. In certain embodiments, the GST layers 220 and 224 protect the heaters 210 and 212 and the top metal 226 from oxidation resulting from the doped GST layer 222. Stated differently, the GST layers 220 and 224 prevent oxygen in the doped GST layer 222 from traveling to the heaters 210 and 212 and to the top metal 226. As a result, the GST layers 220 and 224 prevent damage to the heaters 210 and 212 and the top metal 226, in certain embodiments. As seen in FIG. 5F, contacts 230 and 232 are then formed. The contact 230 is formed to the mask 228 such that the contact 230 allows for an electrical connection to be made to the mask 228 and the top metal 226. The contact 232 is formed to the pad 204 such that the contact 232 allows an electrical connection to be made to the pad 204.

In summary, an artificial intelligence device cell includes a PCM region 218 that includes buffer layers that separate a doped GST layer 222 from a heater 210 and top metal 226. For example, GST layers 220 and 224 may be formed above and below the doped GST layer 222 such that the GST layers 220 and 224 are positioned between the doped GST layer 222 and the heater 210 and top metal 226. As a result, the GST layers 220 and 224 may prevent the doped GST layer 222 from oxidizing and damaging the heater 210 and the top metal 226, in certain embodiments.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present disclosure, other and further embodiments may be devised without departing from the basic scope thereof, and the scope thereof is determined by the claims that follow.

What is claimed is:

1. An apparatus comprising:
a heater;
a phase change material region comprising a doped germanium-antimony-tellurium (GST) layer and a first GST layer, wherein the first GST layer is between the doped GST layer and the heater, and wherein the doped GST layer is doped differently than the first GST layer; and
a top metal layer, wherein the phase change material region is positioned between the heater and the top metal layer.

2. The apparatus of claim 1, further comprising a liner positioned on the heater.

3. The apparatus of claim 2, wherein the liner is positioned within the first GST layer.

4. The apparatus of claim 1, wherein the doped GST layer is at least ten times thicker than the first GST layer.

5. The apparatus of claim 1, wherein the phase change material region further comprises a second GST layer, wherein the doped GST layer is between the first GST layer and the second GST layer, and wherein the doped GST layer is doped differently than the second GST layer.

6. The apparatus of claim 5, wherein the phase change material region further comprises a second doped GST layer and a third GST layer, wherein the second doped GST layer is positioned between the second GST layer and the third GST layer, and wherein the second doped GST layer is doped differently than the second and third GST layers.

7. The apparatus of claim 1, further comprising a contact, wherein the top metal layer is between the contact and the phase change material region.

8. The apparatus of claim 1, wherein the heater is formed in a dielectric, and wherein the phase change material region is positioned on the dielectric.

9. A method comprising:
forming a heater on a pad;
forming a phase change material region on the heater, the phase change material region comprising a doped GST layer and a first GST layer, wherein the first GST layer is between the doped GST layer and the heater, and wherein the doped GST layer is doped differently than the first GST layer; and
forming a top metal layer on the phase change material region.

10. The method of claim 9, further comprising forming a liner on the heater before forming the phase change material region.

11. The method of claim 10, wherein the liner is positioned within the first GST layer after forming the phase change material region.

12. The method of claim 9, wherein the doped GST layer is at least ten times thicker than the first GST layer.

13. The method of claim 9, wherein the phase change material region further comprises a second GST layer, wherein the doped GST layer is between the first GST layer and the second GST layer, and wherein the doped GST layer is doped differently than the second GST layer.

14. The method of claim 13, wherein the phase change material region further comprises a second doped GST layer and a third GST layer, wherein the second doped GST layer is positioned between the second GST layer and the third GST layer, and wherein the second doped GST layer is doped differently than the second and third GST layers.

15. The method of claim 9, further comprising forming a contact, wherein the top metal layer is between the contact and the phase change material region.

16. The method of claim 9, wherein the heater is formed in a dielectric, and wherein the phase change material region is positioned on the dielectric.

17. An apparatus comprising:
a heater; and
a phase change material region comprising a doped GST layer disposed on a first GST layer, wherein the first GST layer is between the doped GST layer and the heater, and wherein the doped GST layer is doped differently than the first GST layer.

18. The apparatus of claim 17, further comprising a liner positioned on the heater.

19. The apparatus of claim 17, wherein the phase change material region further comprises a second GST layer, wherein the doped GST layer is between the first GST layer and the second GST layer, and wherein the doped GST layer is doped differently than the second GST layer.

20. The apparatus of claim 19, wherein the phase change material region further comprises a second doped GST layer and a third GST layer, wherein the second doped GST layer is positioned between the second GST layer and the third GST layer, and wherein the second doped GST layer is doped differently than the second and third GST layers.
